(19) United States
(12) Patent Application Publication
(10) Pub. No.: US 2008/0050875 A1
(43) Pub. Date: Feb. 28, 2008

(54) Methods of fabricating embedded flash memory devices

(76) Inventors: Jung-Ho Moon, Seoul (KR); Chul-Soon Kwon, Seoul (KR); Jae-Min Yu, Anyang-si (KR); Young-Cheon Jeong, Yongin-si (KR); In-Gu Yoon, Uiwang-si (KR); Byeong-Cheol Lim, Busan (KR)

Correspondence Address: LEE & MORSE, P.C., 3141 FAIRVIEW PARK DRIVE, SUITE 500, FALLS CHURCH, VA, 22042, US

(21) Appl. No.: 11/645,576

(22) Filed: Dec. 27, 2006

(30) Foreign Application Priority Data
Aug. 25, 2006 (KR) 2006-81082

(51) Int. Cl. H01L 21/336

(52) U.S. Cl. 438/257

(57) ABSTRACT

A method of fabricating a compound device includes forming a first gate insulating pattern on a semiconductor substrate including a first region and a second region, forming a second gate insulating layer on the first gate insulating pattern, and after forming the second gate insulating layer, forming a well in the second region of the semiconductor substrate.

### BACKGROUND OF THE INVENTION

1. Field of the Invention

The present invention disclosed herein relates to a method of fabricating a semiconductor device. More particularly, the present invention relates to a method of fabricating an embedded flash memory device.

2. Description of the Related Art

As a level of integration of semiconductor devices is increasing, compound chips in which a memory product and a logic product are combined into one chip are being developed in order to meet various demands. Memory devices used in compound chips include a volatile memory device, e.g., a dynamic random access memory (DRAM) and a static RAM (SRAM) and a nonvolatile memory device, e.g., a flash memory. Because the memory and logic products may be realized on a single compound chip, such compound chips may enable miniaturization, low power consumption, high speed and low electromagnetic interference (EMI) noise. Research related to development of the compound chips is being actively performed in a variety of fields.

As representative examples, compound chips may include a merged DRAM-logic (MDL) device in which a DRAM cell and a logic device are merged together, a merged flash-logic (MFL) device in which a flash memory device and a logic device are merged together, etc.

In the MFL device, a method of forming a memory cell gate electrode having a split gate structure using self-aligning techniques is being used. As a control gate electrode is formed in the split gate structure, a coupling ratio of the memory cell is increased as a result of a fine design rule, and a memory cell having a high erase and program efficiency may be formed.

However, to form the compound chips, processing can be difficult because a process of forming a memory device should be considered in conjunction with a process of forming a logic circuit.

In a process of forming a conventional MFL device, an active region is defined in a semiconductor substrate and a floating gate structure is formed on a flash memory cell region. An n-well and a p-well are formed in a logic region, and a tunnel insulating layer is formed on a floating gate electrode of the flash memory cell region. Thereafter, an insulating layer is formed. The insulating layer may be used as an inter-gate insulating layer and a gate insulating layer in the flash memory cell region and the logic region, respectively. Then, a conductive layer pattern including a control gate electrode in the flash memory cell region and a logic gate electrode in the logic region may be formed.

A variety of logic transistors of the logic region should have logic conformity having the designed uniform characteristic current. However, in the process described above, impurity ions which have been implanted for forming the n-well and the p-well in the logic region may excessively diffuse because a process of forming the insulating layer is performed at a high temperature. The excessive diffusion of the impurity ions changes characteristic current flowing through a channel of the logic transistor of the logic region. There is a problem in that the characteristic current may be increased in a logic transistor including a logic gate electrode that has a narrow width, thereby deteriorating the logic conformity of the logic region.

### SUMMARY OF THE INVENTION

The present invention is therefore directed to methods of fabricating an embedded flash memory device, which substantially overcome one or more of the problems due to limitations and disadvantages of the related art.

It is therefore a feature of an embodiment of the present invention to provide a method of fabricating an embedded flash memory device capable of preventing and/or reducing deterioration of logic conformity of a logic region.

At least one of the above and other features and advantages of the present invention may be realized by providing a method of fabricating an embedded flash memory device, the method including defining a first region and a second region on a semiconductor device, forming a floating gate structure on the first region, with a first gate insulating layer pattern interposed therebetween, forming a second gate insulating layer on the first region and the second region of the semiconductor substrate including the floating gate structure, and forming a well in the second region of the semiconductor substrate where the second gate insulating layer is formed.

Defining the first region and the second region may include forming at least one device isolation pattern. The first region and the second region may be a flash memory cell region and a logic region, respectively. The logic region may include a low voltage region and a high voltage region.

Forming a second gate insulating layer on the first region and the second region of the semiconductor substrate may include forming the second gate insulating layer in the high voltage region to be thicker than the first gate insulating layer pattern.

Forming the floating gate structure may include forming a first gate insulating layer on the first region of the semiconductor substrate, forming a first conductive layer on the first gate insulating layer, forming a mask pattern on the first conductive layer, the mask pattern having an opening therein exposing a predetermined region of the first conductive layer, thermally oxidizing the exposed first conductive layer to form an IPO (inter-poly oxide) layer, removing the mask pattern, and etching the first conductive layer and the first gate insulating layer using the IPO layer as a mask to form a floating gate electrode and the first gate insulating layer pattern.

The floating gate structure may include the floating gate electrode and the IPO layer. The IPO layer may have a smaller thickness at edge portions thereof than at a center portion thereof. The first conductive layer may include polysilicon. Forming the second gate insulating layer may include performing a thermal oxidation process on the semiconductor substrate including the floating gate structure to form a thermal oxide layer on a surface of the semiconductor substrate and sidewalls of the floating gate structure, and forming a MTO (medium temperature oxide) layer covering the semiconductor substrate.

Forming the well may include forming a photoresist pattern exposing the second region on the semiconductor substrate, forming the well in the exposed second region of the semiconductor substrate by an ion implantation process using the photoresist pattern as a mask, and removing the photoresist pattern.

Removing the photoresist pattern may include using a boiling H₂SO₄ solution. The method may further include, after forming the well, forming a flash memory cell and a logic transistor on the first region and the second region, respectively. Forming the flash memory cell and the logic transistor may include forming a second conductive layer on the second gate insulating layer; and patterning the second conductive layer and the second gate insulating layer to form a control gate electrode and inter-gate insulating layer on the first region, and a logic gate electrode and a logic gate insulating layer on the second region, wherein the flash memory cell may include the first gate insulating layer pattern, the floating gate structure, the inter-gate insulating layer and the control gate electrode, and the logic transistor may include the logic gate insulating layer and the logic gate electrode. The second conductive layer may include polysilicon.

At least one of the above and other features and advantages of the present invention may be separately realized by providing a method of fabricating a compound device, the method including forming a first gate insulating pattern on a semiconductor substrate including a first region and a second region, forming a second gate insulating layer on the first gate insulating pattern, and after forming the second gate insulating layer, forming a well in the second region of the semiconductor substrate.

The method may further include forming a photoresist pattern over the first region of the semiconductor substrate after forming the second gate insulating layer and before forming the well. The first region may be a flash memory cell region including at least one flash memory cell, and the second region may be a logic region including at least one logic transistor.

Forming the second gate insulating pattern may include forming a thermal oxide layer and forming a medium temperature oxide layer over the thermal oxide layer. Forming the thermal oxide layer may include a thermal oxidation process performed at a temperature of about 800° C. to about 900° C.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 through 8 illustrate cross-sectional views of stages in a method of fabricating an embedded flash memory device according to one or more aspects of the invention.

### DETAILED DESCRIPTION OF THE INVENTION

Korean Patent Application No. 2006-81082, filed on Aug. 25, 2006, in the Korean Intellectual Property Office, and entitled: “Method of Fabricating Embedded Flash Memory Device,” is incorporated by reference herein in its entirety.

Exemplary embodiments of the present invention will be described below in more detail with reference to the accompanying drawings. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout the specification.

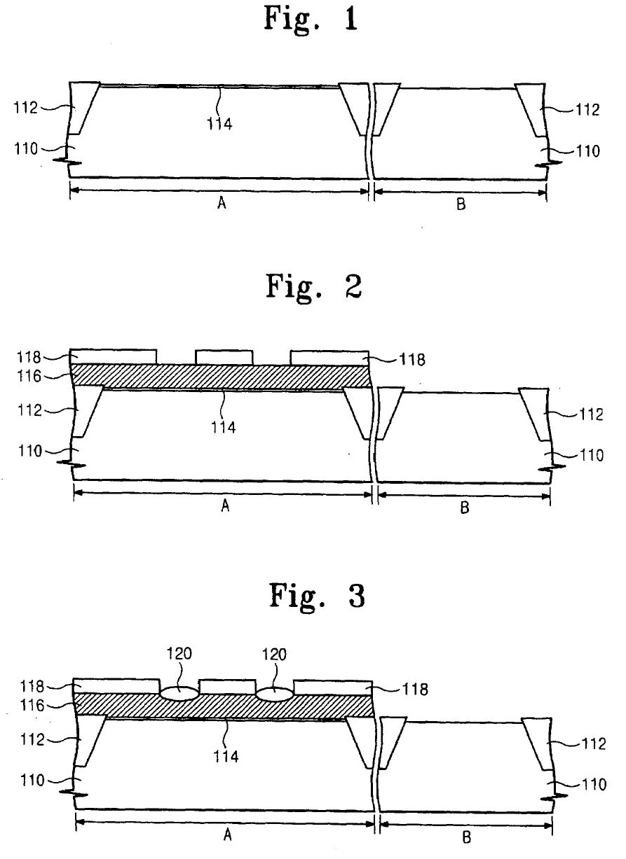

FIGS. 1 through 8 illustrate cross-sectional views of stages in a method of fabricating an embedded flash memory device according to one or more aspects of the invention. More particularly, an exemplary method of fabricating an embedded split gate type flash memory device according to an embodiment of the present invention will be described below.

Referring to FIG. 1, device isolation pattern(s) 112 may be formed in a semiconductor substrate 110, and the device isolation pattern(s) 112 may define an active region. The semiconductor substrate 110 may include a plurality of different regions, e.g., a flash memory cell region A, a logic region B. The flash memory cell region A may correspond to a region(s) where flash memory cells are disposed. The logic region B may correspond to region(s) where logic transistors are disposed. The logic region B may include a low voltage region and a high voltage region. The logic region B may include an NMOS region and a PMOS region.

As shown in FIG. 1, a first gate insulating layer 114 may be formed over the semiconductor substrate 110. For example, as shown in FIG. 2, the first gate insulation layer 114 may cover the flash memory cell region A of the semiconductor substrate 110. The first gate insulating layer 114 may include, e.g., a silicon oxide layer formed by, e.g., a thermal oxidation process. In some embodiments of the invention, the first gate insulating layer 114 may have a thickness of about 60 Å to about 100 Å. The thermal oxidation process may include oxidizing a surface of the semiconductor substrate 110 at a temperature of about 800° C. to about 900° C. using, e.g., oxygen (O₂) as an oxidation gas and then using an N₂O annealing method.

Referring to FIG. 2, a first conductive layer 116 may be formed on the first gate insulating layer 114 in the flash memory cell region A. The first conductive layer 116 may include, e.g., polysilicon. In some embodiments, the first conductive layer 116 may have a thickness of about 600 Å to about 1,200 Å using, e.g., a chemical vapor deposition (CVD) process.

A mask layer (not shown) may be formed on the first conductive layer 116. The mask layer may then be patterned to form a mask pattern 118. The mask pattern 118 may include an opening therein that exposes a predetermined region of the first conductive layer 116. The opening may be formed using, e.g., a photolithography etching process. The mask layer may include, e.g., a silicon nitride layer (SiₓN_{y}). More particularly, the mask layer may be, e.g., a silicon nitride layer formed using, e.g., a CVD process.

Referring to FIG. 3, a portion(s) of the first conductive layer 116 exposed by the mask pattern 118 may then be thermally oxidized to form, e.g., an inter-poly oxide (IPO) layer 120. The IPO layer 120 may be disposed on an upper portion of the exposed first conductive layer 116. In some embodiments, a cross-sectional shape of the IPO layer 120 may be, e.g., an eye-like shape. That is, in some embodiments, a thickness of edge portion(s) of the IPO layer 120 may be thinner than a thickness of center portion(s) of the IPO layer 120. In some embodiments, the center portion(s) of the IPO layer 120 may have a thickness of about 1,000 Å to about 1,400 Å. The IPO layer 120 may be formed by, e.g., a thermal oxidation process at a temperature of, e.g., about 800° C. to about 900° C.

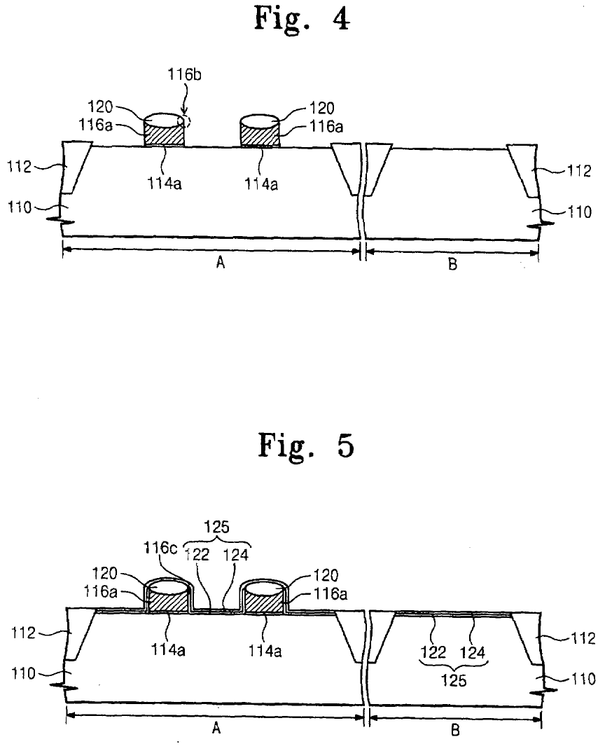

Referring to FIG. 4, the mask pattern 118 may then be removed, and thereafter the first conductive layer 116 and the first gate insulating layer 114 may be etched using the IPO layer 120 as an etch mask to form a floating gate structure on a predetermined region of the flash memory cell region A of the semiconductor substrate 110. The floating gate structure may include a floating gate electrode 1 16a on the semiconductor substrate 110 with a gate insulating layer pattern 114a interposed between the floating gate electrode 116a and the semiconductor substrate 110, and the IPO layer 120 on the floating gate electrode 116a. The floating gate electrode 116a may include edges 116b having a shape corresponding to the shape of the IPO layer 120. For example, the edges 116b of the floating gate electrode 116a may be tapered or pointed. More particularly, the shape of the edges 116b may result from the etching process used to form the floating gate electrode 116a, which may have employed the IPO layer 120 as an etching mask. As the floating gate electrode 116a may include the pointed edge(s) 116b, an erase efficiency of the flash memory cell may be improved.

With regard to the logic region B, the first gate insulating layer 114, the first conductive layer 116 and the mask pattern 118, which may also have been formed in the logic region B during the stages of the exemplary method illustrated in FIGS. 1 to 4, may be removed after each respective process of forming the respective layer or may be removed during the process of forming the floating gate structure illustrated in FIG. 4.

Referring to FIG. 5, a second gate insulating layer 125 may then be formed on the flash memory cell region A and the logic region B of the semiconductor substrate 110 including the floating gate structure. The process of forming the second gate insulating layer 125 may include performing a thermal oxidation process on the semiconductor substrate 110 and forming a medium temperature oxide (MTO) layer 124 covering the semiconductor substrate 110. As shown in FIG. 5, the thermal oxidation process may form a thermal oxide layer 122 on a surface of the semiconductor substrate 110 and sidewalls 116c of the floating gate electrode 116a. The thermal oxidation process that may be used to form the thermal oxide layer 122 may be performed at a temperature of about 800° C. to about 900° C. In some embodiments of the invention, the second insulating layer 125 may include the thermal oxide layer 122 and the MTO layer 124.

Over the flash memory cell region A, the second insulating layer 125 over the flash memory cell region A may include the thermal oxide layer 122 and the MTO layer 124. The thermal oxide layer 122 may be formed on the sidewalls 116c of the floating gate electrode 116a and may serve as a tunnel insulating layer employable during an erase operation of the flash memory cell. In some embodiments of the invention, in the flash memory cell region A, the thermal oxide layer 122 may have a thickness of about 50 Å to about 150 Å.

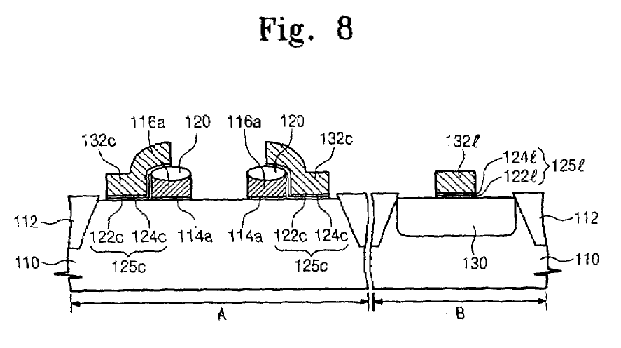

As shown in FIG. 5, the MTO layer 124 may cover the floating gate structure including the thermal oxide layer 122. The MTO layer 124 may serve as an inter-gate insulating layer for insulating the floating gate electrode 116a of the flash memory cell and a control gate electrode (see 132c of FIG. 8) from each other. In some embodiments, the MTO layer 124 may have a thickness of about 80 Å to about 150 Å. The MTO layer 124 may be formed using, e.g., a low pressure chemical vapor deposition (LP-CVD) process at a temperature of about 700° C. to about 800° C.

Over the logic region B, the second gate insulating layer 125 may include another portion of the thermal oxide layer 122 and another portion of the MTO layer 124. The second gate insulating layer 125 over the logic region B may serve as a logic gate insulating layer pattern (see 125l of FIG. 8) in the logic transistor(s). Additionally, the second gate insulating layer 125 over the logic region B may have a greater thickness than that of a thickness of the first gate insulating layer 114. In such cases, e.g., the second gate insulating layer 125 over the logic region B may be used as the gate insulating layer of a high voltage transistor in a high voltage region that may be included in the logic region B.

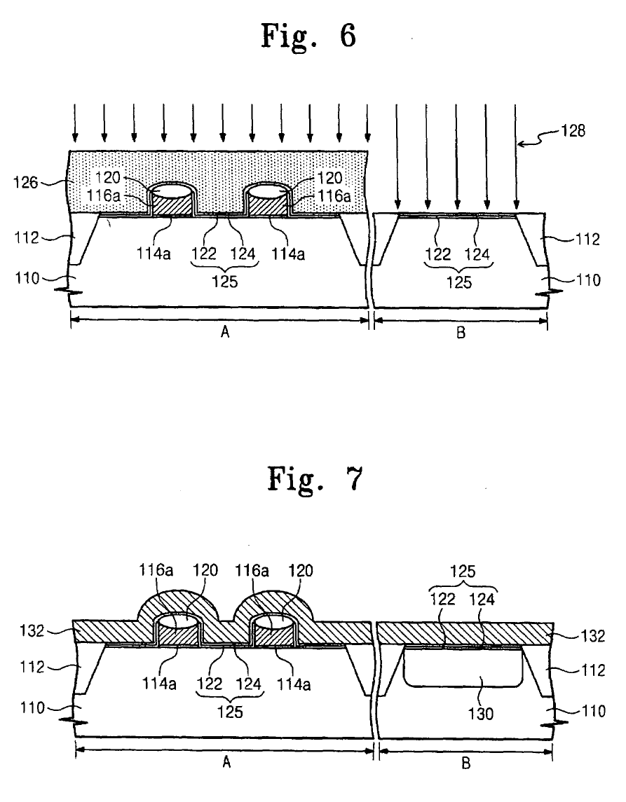

Referring to FIGS. 6 and 7, a photoresist pattern 126 may be formed on the semiconductor substrate 110 to cover the flash memory cell region A and expose the logic region B. The photoresist pattern 126 may be formed using, e.g., a photolithography etching process. A well region 130 may be formed within the exposed logic region B of the semiconductor substrate 110. The well region 130 may be formed by, e.g., an ion implantation process 128 using the photoresist pattern 126 as a mask. The well region 130 may include an n-well and a p-well, which may be independently formed.

In some embodiments, the well region 130 may be formed to a depth of about 4,000 Å using, e.g., an ion implantation process 128. The ion implantation process 128 may be performed at an implantation dose of, e.g., about 1×10¹² atoms/cm² and an implantation energy of, e.g., several hundreds of kiloelectron volt (keV). A group 5B (VB) element, e.g., phosphorus (P), may be implanted into the n-well as impurity ions. A group 3B (IIIB) element, e.g., boron (B), may be implanted into the p-well as impurity ions. A channel region may be further formed on a surface of the semiconductor substrate 110 defined as the well region 130 using, e.g., an ion implantation process at, e.g., an implantation dose of, e.g., about 1×10¹² atoms/cm² and an implantation energy of about, e.g., several tens kiloelectron volt (keV).

In embodiments of the invention, the n-well and p-well may be formed in the logic region B after forming the second gate insulating layer 125 at a high temperature. Thus, embodiments of the invention may prevent and/or reduce excessive diffusion of the impurity ions implanted for forming the n-well and the p-well in the logic region B. Accordingly, embodiments of the invention may prevent and/or reduce an increase or decrease in a charateristic current flowing through a channel of the logic transistor of the logic region B. As a result, a variety of logic transistors of the logic region B can maintain a logic conformity having the designed uniform characteristic current. Also, the second insulating layer 125 may be formed shortly after forming the floating gate structure, and thus, may reduce and/or prevent pollution and/or damage to the floating gate structure, which may occur during subsequent process(es). Therefore, embodiments of the invention may enable reliability of the flash memory cell to be improved.

Referring to FIG. 7, the photoresist pattern 126, which may have been used as a mask in the ion implantation process 128 for forming the well region 130, may then be removed. When removing the photoresist pattern 126, the second gate insulating layer 125 should be retained. Thus, in some embodiments, a boiling H₂SO₄ solution may be used for removing the photoresist pattern 126. More particularly, the photoresist pattern 126 may be removed using the boiling H₂SO₄ solution to prevent removal of the second gate insulating layer 125 that may be used as the gate insulating layer of the high voltage transistor(s) that may be formed in the high voltage region included in the logic region B. Therefore, stable operation characteristics of the high voltage transistor can be implemented.

A second conductive layer 132 may be formed on the second gate insulating layer 125. The second conductive layer 132 may include, e.g., polysilicon. In some embodiments, the second conductive layer 132 may have a thickness of about 1,000 Å to about 3,000 Å using, e.g., the CVD process at a temperature of, e.g., about 600° C. to about 700° C.

Referring to FIG. 8, the second conductive layer 132 and the second gate insulating layer 125 may be patterned to form the flash memory cell and the logic transistor in the flash memory cell region A and the logic region B, respectively. The flash memory cell may include the floating gate structure, an inter-gate insulating layer 125c covering portions of an upper portion and one sidewall of the floating gate structure and a control gate electrode 132c. The inter-gate insulating layer 125c may include a thermal oxide layer a first thermal oxide layer pattern 122c and a first MTO layer pattern 124c. The logic transistor may include a logic gate insulating layer 125l and a logic gate electrode 132l. The logic gate insulating layer 125l may include a second thermal oxide layer pattern 122l and a second MTO layer pattern 124l.

When the embedded flash memory device is fabricated one or more aspects of the present invention, it is possible to prevent and/or reduce excessive diffusion of the impurity ions implanted for forming the n-well and the p-well of the logic region of a compound chip. Therefore, embodiments of the invention provide a method of fabricating the embedded flash memory device capable of preventing and/or reducing deterioration of the logic conformity of the logic region.

Additionally, pollution which may occur during subsequent processing of the floating gate electrode may be minimized to provide a method of fabricating the embedded flash memory device including the flash memory device having stable operation characteristics.

As described above, according to aspects of the invention, deterioration of the logic conformity of the logic region may be reduced and/or prevented and embedded flash memory device(s) having the improved reliability may be fabricated.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of fabricating an embedded flash memory device, the method comprising:
defining a first region and a second region on a semiconductor device;
forming a floating gate structure on the first region, with a first gate insulating layer pattern interposed therebetween;
forming a second gate insulating layer on the first region and the second region of the semiconductor substrate including the floating gate structure; and
forming a well in the second region of the semiconductor substrate where the second gate insulating layer is formed.

2. The method as claimed in claim 1, wherein defining the first region and the second region comprises forming at least one device isolation pattern.

3. The method as claimed in claim 1, wherein the first region and the second region are a flash memory cell region and a logic region, respectively.

4. The method as claimed in claim 3, wherein the logic region comprises a low voltage region and a high voltage region.

5. The method as claimed in claim 4, wherein forming a second gate insulating layer on the first region and the second region of the semiconductor substrate comprises forming the second gate insulating layer in the high voltage region to be thicker than the first gate insulating layer pattern.

6. The method as claimed in claim 1, wherein forming the floating gate structure comprises:
forming a first gate insulating layer on the first region of the semiconductor substrate;
forming a first conductive layer on the first gate insulating layer;
forming a mask pattern on the first conductive layer, the mask pattern having an opening therein exposing a predetermined region of the first conductive layer;
thermally oxidizing the exposed first conductive layer to form an IPO (inter-poly oxide) layer;
removing the mask pattern; and
etching the first conductive layer and the first gate insulating layer using the IPO layer as a mask to form a floating gate electrode and the first gate insulating layer pattern.

7. The method as claimed in claim 6, wherein the floating gate structure comprises the floating gate electrode and the IPO layer.

8. The method as claimed in claim 6, wherein the IPO layer has a smaller thickness at edge portions thereof than at a center portion thereof.

9. The method as claimed in claim 6, wherein the first conductive layer comprises polysilicon.

10. The method as claimed in claim 1, wherein forming the second gate insulating layer comprises:
performing a thermal oxidation process on the semiconductor substrate including the floating gate structure to form a thermal oxide layer on a surface of the semiconductor substrate and sidewalls of the floating gate structure; and
forming an MTO (medium temperature oxide) layer covering the semiconductor substrate.

11. The method as claimed in claim 1, wherein forming the well comprises:
forming a photoresist pattern exposing the second region on the semiconductor substrate;
forming the well in the exposed second region of the semiconductor substrate by an ion implantation process using the photoresist pattern as a mask; and
removing the photoresist pattern.

12. The method as claimed in claim 11, wherein removing the photoresist pattern comprises using a boiling H₂SO₄ solution.

13. The method as claimed in claim 1, further comprising, after forming the well, forming a flash memory cell and a logic transistor on the first region and the second region, respectively.

14. The method as claimed in claim 13, wherein forming the flash memory cell and the logic transistor comprises:
forming a second conductive layer on the second gate insulating layer; and
patterning the second conductive layer and the second gate insulating layer to form a control gate electrode and inter-gate insulating layer on the first region, and a logic gate electrode and a logic gate insulating layer on the second region,
wherein the flash memory cell comprises the first gate insulating layer pattern, the floating gate structure, the inter-gate insulating layer and the control gate electrode, and the logic transistor comprises the logic gate insulating layer and the logic gate electrode.

15. The method as claimed in claim 14, wherein the second conductive layer comprises polysilicon.

16. A method of fabricating a compound device, the method comprising:
forming a first gate insulating pattern on a semiconductor substrate including a first region and a second region;
forming a second gate insulating layer on the first gate insulating pattern; and
after forming the second gate insulating layer, forming a well in the second region of the semiconductor substrate.

17. The method as claimed in claimed 16, further comprising forming a photoresist pattern over the first region of the semiconductor substrate after forming the second gate insulating layer and before forming the well.

18. The method as claimed in claim 17, wherein the first region is a flash memory cell region including at least one flash memory cell, and the second region is a logic region including at least one logic transistor.

19. The method as claimed in claim 16, wherein forming the second gate insulating pattern comprises forming a thermal oxide layer and forming a medium temperature oxide layer over the thermal oxide layer.

20. The method as claimed in claim 19, wherein forming the thermal oxide layer comprises a thermal oxidation process performed at a temperature of about 800° C. to about 900° C.
